(19) United States
(12) Patent Application Publication
(10) Pub. No.: US 2012/0147312 A1
(43) Pub. Date: Jun. 14, 2012

(54) DISPLAY DEVICE INCLUDING WIRINGS OF DIFFERENT THICKNESSES AND METHOD OF MANUFACTURING THE SAME

(75) Inventors: Hyung-Jun KIM, Yongin-si (KR); Chang-Oh JEONG, Suwon-si (KR)

(73) Assignee: SAMSUNG ELECTRONICS CO., LTD., Suwon-si (KR)

(21) Appl. No.: 13/287,512

(22) Filed: Nov. 2, 2011

(30) Foreign Application Priority Data
Dec. 10, 2010 (KR) 10-2010-0126339

(51) Int. Cl. G02F 1/1343; H01L 33/08

(52) U.S. Cl. 349/139; 438/34; 257/E33.012

(57) ABSTRACT

Provided are a display device and a method of manufacturing the same. The display device includes: a substrate divided into a display area and a peripheral area; a first metal wiring formed on the display area of the substrate; and a second metal wiring formed on the peripheral area of the substrate and including a gate driver. The first metal wiring is thicker than the second metal wiring.

This application claims priority from Korean Patent Application No. 10-2010-0126339 filed on Dec. 10, 2010, which is hereby incorporated by reference for all purposes as if fully set forth herein.

### BACKGROUND OF THE INVENTION

1. Field of the Invention

Aspects of the present invention relate to a display device including a low resistance wiring and a method of manufacturing the display device.

2. Description of the Related Art

As the demand for liquid crystal displays (LCDs) having larger screens and higher resolution has increased, the length of wiring included therein is being increased, and the line width of the wiring is being reduced. Accordingly, this leads to a sharp increase in resistivity and capacitance values of the wiring, causing image distortion due to signal delays. In this situation, the development of low resistance wiring is being recognized as a core technology for the development of large-screen and high-resolution LCDs. As one of materials for low resistance wirings, copper is drawing attention. This is because copper, which is superior in charge mobility and has lower electrical resistance than conventional materials such as aluminum, molybdenum and chrome, can solve the problem of resistive-capacitive (RC) delay of driving signals.

To form fine patterns on a substrate, a metal is deposited on the entire surface of the substrate by sputtering. Then, patterns are formed by a photolithography process using a photoresist. Such conventional methods of forming a metal wiring require expensive equipment and involve sputtering at a high temperature. Accordingly, many processes are required, and investment costs for manufacturing facilities are high, thus raising manufacturing costs.

### SUMMARY OF THE INVENTION

Aspects of the present invention provide a display device in which a low resistance wiring formed by plating is included in a display area, to reduce resistive-capacitive (RC) delay, but is not included in a driver, to enable the driver to operate properly.

Aspects of the present invention also provide a method of manufacturing the display device, in which wrings of the driver and the display area are formed simultaneously.

However, aspects of the present invention are not restricted to the one set forth herein. The above and other aspects of the present invention will become more apparent to one of ordinary skill in the art to which the present invention pertains, by referencing the detailed description of the present invention given below.

According to an aspect of the present invention, there is provided a display device including: a substrate divided into a display area in which an image is displayed and a peripheral area; a first metal wiring formed on the display area of the substrate; and a second metal wiring formed on the peripheral area of the substrate and including a gate driver, wherein the first metal wiring is thicker than the second metal wiring.

According to another aspect of the present invention, there is provided a method of manufacturing a display device. The method includes: forming a base metal layer on a substrate which is divided into a first region and a second region; forming a first photosensitive pattern having a first thickness on the base metal layer and in the first region; forming a second photosensitive pattern having a second thickness, which is greater than the first thickness, on the base metal layer and in the second region; etching the base metal layer using the first and second photosensitive patterns as a mask; removing the first photosensitive pattern and reducing the thickness of the second photosensitive pattern; and forming a plating layer on the base metal layer of the first region, by electrolytic or electroless plating.

According to another aspect of the present invention, there is provided a method of manufacturing a display device. The method includes: forming a gate wiring, which includes a gate electrode, on a substrate divided into a first region and a second region; forming an active layer on the gate electrode by forming a gate insulating film, an amorphous or polycrystalline silicon film, and a doped amorphous silicon film on the gate electrode, and patterning the amorphous or polycrystalline silicon film and the doped amorphous silicon film; forming a base metal layer on the active layer; forming a first photosensitive pattern having a first thickness on the base metal layer and in the first region; forming a second photosensitive pattern having a second thickness, which is greater than the first thickness, on the base metal layer and in the second region; etching the base metal layer by using the first and second photosensitive patterns as a mask; etching the doped amorphous silicon film to expose a predetermined region of the active layer by using the first and second photosensitive patterns as a mask; removing the first photosensitive pattern and reducing the thickness of the second photosensitive pattern; and forming a source electrode and a drain electrode on the base metal layer and in the first region, by electrolytic or electroless plating.

It is to be understood that both the foregoing general description and the following detailed description are exemplary and explanatory and are intended to provide further explanation of the invention as claimed.

### BRIEF DESCRIPTION OF THE DRAWINGS

The above and other aspects and features of the present invention will become more apparent by describing in detail exemplary embodiments thereof with reference to the attached drawings.

FIG. 1 is a block diagram of a liquid crystal display (LCD), according to an exemplary embodiment of the present invention.

FIG. 2 is a partial layout diagram of a gate driver and a display area of the LCD according to the exemplary embodiment of FIG. 1.

FIG. 3 is a cross-sectional view taken along the lines I-I′ and II-II′ of FIG. 2;

FIG. 4 is a flowchart illustrating a method of manufacturing an LCD according to an exemplary embodiment of the present invention.

FIGS. 5A, 5B, 5C, 5D, 5E, 5f, 5G, and 5H are cross-sectional views respectively illustrating processes of the method of manufacturing an LCD, according to the exemplary embodiment of FIG. 4.

FIG. 6 is a flowchart illustrating a method of manufacturing an LCD, according to another exemplary embodiment of the present invention.

FIGS. 7 and 8 are cross-sectional views respectively illustrating processes of the method of manufacturing an LCD, according to the exemplary embodiment of FIG. 6.

FIG. 9 is a flowchart illustrating a process of forming a data wiring in the method of manufacturing an LCD, according to the exemplary embodiment of FIG. 6.

FIGS. 10A, 10B, 10C, 10D, 10E, 10F, 10G, 10H, 10I, 11, 12, and 13 are cross-sectional views respectively illustrating processes of the method of manufacturing an LCD, according to the exemplary embodiment of FIG. 6.

### DETAILED DESCRIPTION OF THE EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

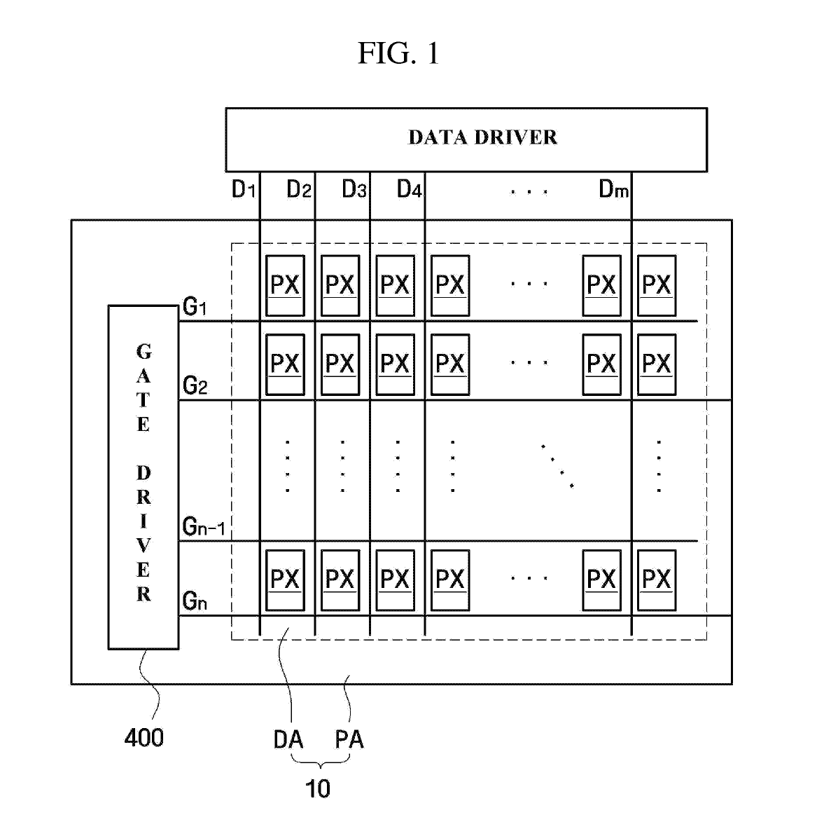

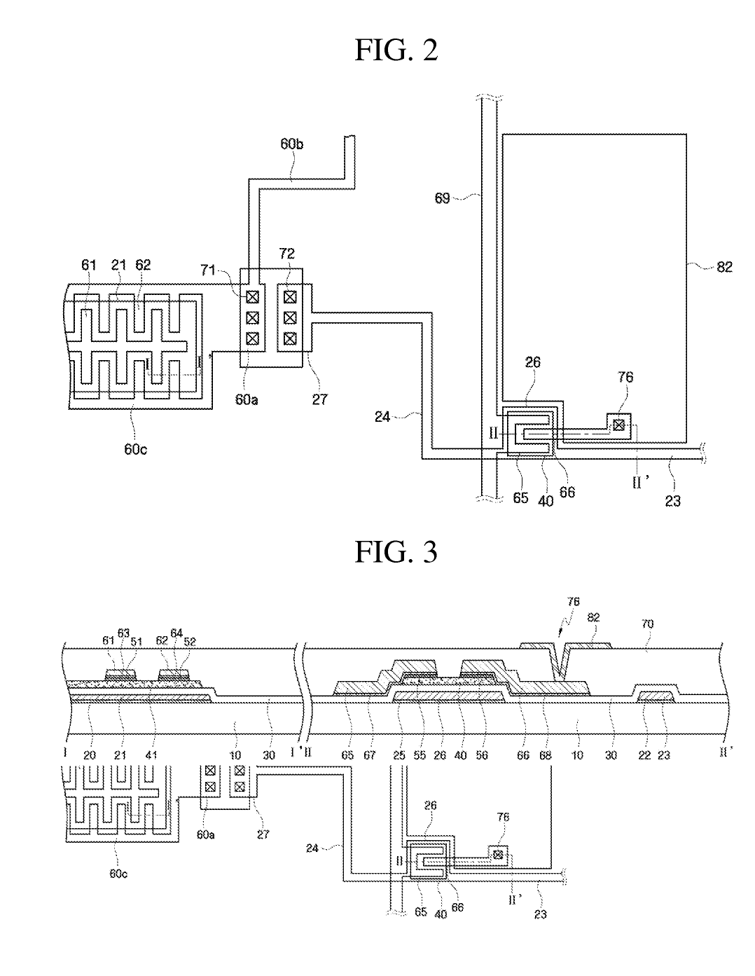

FIG. 1 is a block diagram of a liquid crystal display (LCD), according to an exemplary embodiment of the present invention. FIG. 2 is a partial layout diagram of a gate driver 400 and a display area DA of the LCD of FIG. 1. FIG. 3 is a cross-sectional view taken along the lines I-I′ and II-II′ of FIG. 2.

While the present invention is described in terms of a LCD, the present invention is not limited to any particular type of display device. In particular, this invention applies to any type of display including a gate driver, such as, an LCD, an organic light emitting diode (OLED) display, a field effect display (FED), an electrophoretic display apparatus, and the like.

Referring to FIG. 1, the LCD includes a first substrate 10 that is divided into the display area DA and a peripheral area PA. The gate driver 400 is formed on the peripheral area PA. The display area DA is a region which displays an image, together with, a second substrate (not shown), and a liquid crystal layer (not shown) interposed between the first substrate 10 and the second substrate. The peripheral area PA is a region disposed, in which no image is displayed, because the first substrate 10 is wider than the second substrate (not shown). The peripheral area PA is a peripheral region disposed outside the display area DA.

Referring to FIG. 1, the LCD includes a first metal wiring that includes gate lines G1 through Gn that extend on the first substrate 10 in a first direction, and data lines D1 through Dm are insulated from, and extend across, the gate lines G1 through Gn. Pixel regions PX are formed between the gate lines G1 through Gn and the data lines D1 through Dm.

Referring to FIGS. 1, 2, and 3, the first metal wiring includes a gate line 23 (which may be any of gate lines G1 through Gn), a gate electrode 26, a data line 69 (which may be any one of data lines D1 through Dm), a source electrode 65, and a drain electrode 66, and is formed on the display area DA. A thin-film transistor is formed in each pixel region PX. The shown thin-film transistor includes the gate electrode 26, which is connected to the gate line 23, the source electrode 65, which is connected to the data line 69, and the drain electrode 66, which faces the source electrode 65. The pixel electrode 82 is connected to the drain electrode 66 through a contact hole 76. An active layer 40 is interposed between the gate electrode 26 and the source and drain electrodes 65 and 66. The active layer 40 includes amorphous silicon or polycrystalline silicon. Ohmic contact layers 55 and 56 are disposed on the active layer 40, to reduce contact resistance between the active layer 40 and the source and drain electrodes 65 and 66. The ohmic contact layers 55 and 56 include amorphous silicon doped with impurities. A gate insulating film 30 may be formed on the gate electrode 26. The gate line 23, the gate electrode 26, the source electrode 65, and the drain electrode 66 may further include contact layers 22, 25, 67, and 68, respectively, to increase adhesion of the gate line 23, the gate electrode 26, the source electrode 65, and the drain electrode 66, to the substrate 10.

A gate driver 400 may be formed on the peripheral area PA of the first substrate 10. Although not shown in the drawings, two gate drivers 400 may be formed on opposing sides of the peripheral area PA. The gate driver 400 is connected to the gate lines G1 through Gn and sequentially transmits gate signals to the gate lines G1 through Gn. The gate driver 400 transmits a gate clock signal, which is either a gate-on voltage Von or a gate-off voltage Voff, to each of the gate lines G1 through Gn.

The gate driver 400 includes a plurality of stages ST₁ through STₙ₊₁ (not shown), where n is a natural number. The stages ST₁ through STₙ₊₁ are connected to each other in a cascade manner. The stages ST₁ through STₙ, excluding the last stage STₙ₊₁, are connected to the gate lines G1 through Gn, respectively, and respectively output gate signals Gout₍₁₎ through Gout₍ₙ₎ to the gate lines G1 through Gn.

Referring to FIGS. 2 and 3, each stage includes a plurality of thin-film transistors. Each of the thin-film transistors includes a gate electrode 21 formed on the first substrate 10, an active layer 41 including amorphous silicon or polycrystalline silicon formed on the gate electrode 21, and drain and source electrodes 61 and 62 formed on the active layer 41. Additionally, ohmic contact layers 51 and 52 are interposed between the active layer 41 and the drain and source electrodes 61 and 62, to reduce a contact resistance there between. The gate insulating film 30 may be formed on the gate electrode 21.

The drain electrode 61 may be shaped like a fishbone antenna and may overlap the gate electrode 21. A second source or drain line 60c surrounds the drain electrode 61. The source electrode 62 branches from the second source or drain line 60c and face the drain electrode 61. The source electrode 62 may overlap the gate electrode 21. Portions of the drain electrode 61 and the source electrode 62 may be substantially interleaved. The gate electrode 21, the drain electrode 61, and the source electrode 62 may further include contact layers 20, 63, and 64, respectively, for increasing adhesion of the gate electrode 21, the drain electrode 61, and the source electrode 62 to other layers adjacent thereto.

The source electrode 62 provides a gate output signal. A source contact portion 60a connected to the source electrode 62 delivers a gate output signal to a gate line contact portion 27. The gate line contact portion 27 is connected to a gate line 24. A gate output signal transmitted from the source electrode 62 is delivered to the gate electrode 26, via the gate line 24. In addition, a gate output signal of a current stage is delivered to a previous stage, via the source contact portion 60a and a first source or drain line 60b connected to the source contact portion 60a. That is, a second metal wiring, including the gate line 24, the gate electrode 21, the source electrode 62, the drain electrode 61, and the first and second source or drain lines 60b and 60c is formed in the gate driver 400.

As shown in FIG. 3, the first metal wiring of the display area DA is thicker than the second metal wiring of the gate driver 400, which is disposed in the peripheral area PA. The first metal wiring of the display area DA may be formed by electrolytic or electroless plating. In addition, the first metal wiring may include/be disposed on a base metal layer formed by sputtering and a plating layer formed on the base metal layer. Specifically, the base metal layer may be formed as a seed layer by, e.g., sputtering. Then, a plating layer may be formed on the base metal layer by electrolytic or electroless plating, until the base metal layer and the plating layer have a combined thickness of about 5,000 to 20,000 Å.

The second metal wiring of the gate driver 400 may be formed by, e.g., sputtering. The second metal wiring may include the same type of material as the base metal layer of the first metal wiring. The second metal wiring may be formed to a thickness of about 1,000 to 4,000 Å. When the second metal wiring has a thickness of 1,000 Å or more, its resistance is reduced, resulting in a reduction in a resistive-capacitive (RC) delay. When the second metal wiring has such a thickness, there is no problem with the operation of the gate driver 400. However, when the second metal wiring is formed thickness greater than 4,000 Å by electrolytic or electroless plating, a plating layer may grow laterally into a channel region and may have a high surface roughness. Thus, the gate driver 400 may not operate properly. In the current exemplary embodiment, the second metal wiring is not formed by electrolytic or electroless plating, unlike the first metal wiring.

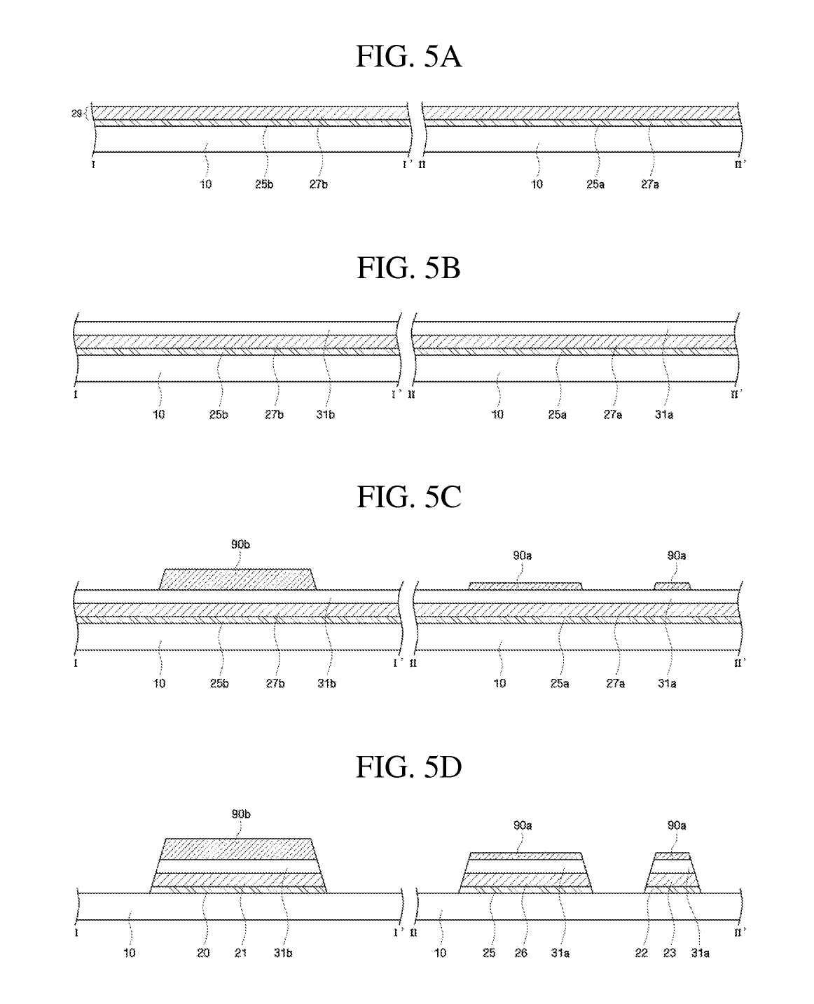

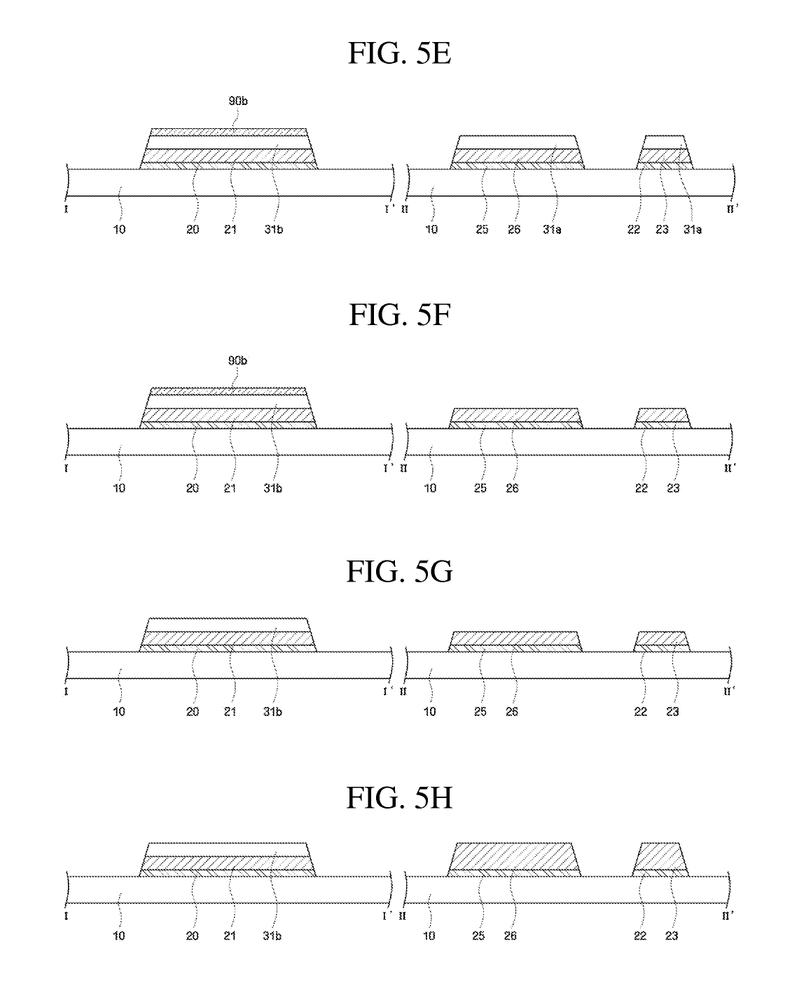

The first metal wiring of the display area DA and the second metal wiring of the peripheral area PA may include aluminum (Al), an aluminum alloy, silver (Ag) a silver alloy, copper (Cu), a copper alloy, molybdenum (Mo), a molybdenum alloy, chrome (Cr), titanium (Ti), or tantalum (Ta). As shown in FIG. 5A, each of the first metal wiring and the second metal wiring may include a layer 26 (26a and 26b) made of copper or a copper alloy, and a titanium layer 25a and 25b, which enhances contact characteristics of the copper layer with other layers.

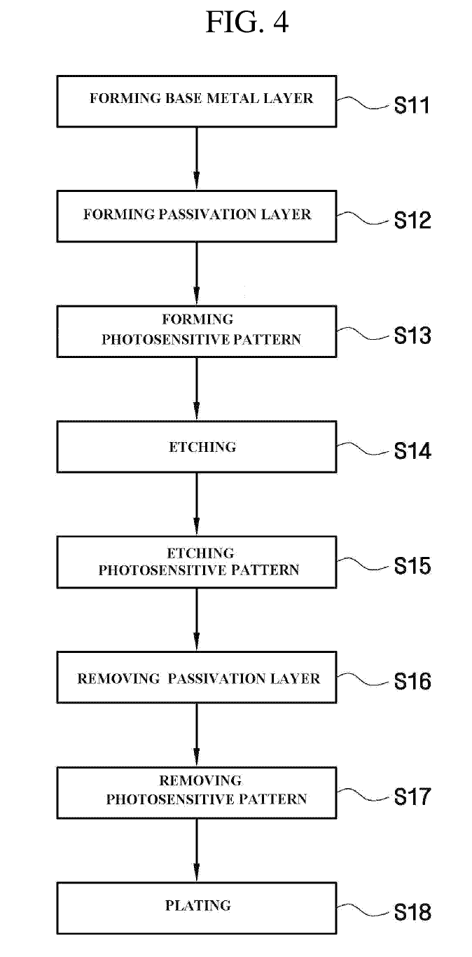

FIG. 4 is a flowchart illustrating a method of manufacturing an LCD, according to an exemplary embodiment of the present invention. Referring to FIG. 4, the method of manufacturing an LCD includes forming a base metal layer (operation S11), forming a passivation layer (operation S12), forming a photosensitive pattern (operation S13), performing an etching process (operation S14), etching the photosensitive pattern (operation S15), removing the passivation layer (operation S16), removing the photosensitive pattern (operation S17), and performing a plating process (operation S18).

FIGS. 5A through 5H are cross-sectional views respectively illustrating the operations of FIG. 4. FIGS. 5A through 5H are cross-sections taken along the lines I-I′ and II-II′ of FIG. 2.

Referring to FIG. 5A, a base metal layer 29 is formed on the substrate 10 (operation S11). In particular, the base metal layer 29 may include an upper layer 27 and a lower layer 25. The upper and lower layers 25 and 27 include first portions 25a and 27a disposed in a display area of the substrate 10, and second portions 25b and 27b disposed in a peripheral area of the substrate 10. Specifically, the upper and lower layers 25 and 27 are formed on the substrate 10 by, e.g., sputtering. The base metal layer 29 may operate as a seed layer for an electrolytic or electroless plating process, which will be described later.

A gate driver may be formed on the peripheral area PA. The substrate 10 may be made of a transparent insulating material, such as glass or plastic.

The upper and lower layers 25 and 27 may be made of may be made of aluminum (Al), an aluminum alloy, silver (Ag) a silver alloy, copper (Cu), a copper alloy, molybdenum (Mo), a molybdenum alloy, chrome (Cr), titanium (Ti), or tantalum (Ta), for example. As shown in FIG. 5A, the upper layer 27 may be made of copper or a copper alloy, and the lower layer 25 may be formed of titanium. In the alternative, the base metal layer 29 may be formed as a single layer including copper or a copper alloy. Copper has low resistivity and superior electron mobility. Thus, a low resistance wiring can be realized with copper. Titanium, which exhibits better contact characteristics than copper, increases the adhesion of the base metal layer 29 to the substrate 10.

The base metal layer 29 may be formed to a thickness of approximately 1,000 to 4,000 Å. When the base metal layer 29 includes a copper upper layer 27 and a titanium lower layer 25, the copper upper layer 27 may be formed to a thickness of approximately 1,000 to 4,000 Å, and the titanium lower layers 25 may be formed to a thickness of approximately 100 to 500 Å. Within such a range, the base metal layer 29 can reduce resistance in the gate driver and can prevent the warping of the substrate 10.

Referring to FIG. 5B, a passivation layer 31 is formed on the base metal layer 29 (operation S12). Specifically, the passivation layer 31 may include a first portion 31a disposed in the display area, and a second portion 31b disposed in the peripheral area. The passivation layer 31 may be an insulating film formed by, e.g., chemical vapor deposition (CVD). The passivation layer 31 may be made of an inorganic material, such as silicon nitride or silicon oxide, or a low-k insulating material formed by plasma enhanced chemical vapor deposition (PECVD), such as a-Si:C:O or a-Si:O:F. The passivation layer 31 may include an inorganic film layer and an organic film layer. The forming of the passivation layer (operation S12) can be omitted.

Referring to FIG. 5C, a first photosensitive pattern 90a having a first thickness is formed on the first portion 31a of the passivation layer 31, and a second photosensitive pattern 90b having a second thickness, which is greater than the first thickness, is formed on the second portion 31b of the passivation layer 31 (operation S13). Specifically, a photosensitive film is coated on the first and second portions 31a and 31b of the passivation layer 31. Then, the photosensitive film is patterned by exposing the photosensitive film to light using a slit mask or a halftone mask, and developing the exposed photosensitive film. Accordingly, the first photosensitive pattern 90a is formed on the first portion 31a of the passivation layer 31, and the second photosensitive pattern 90b is formed on the second portion 31b of the passivation layer 31. That is, photosensitive patterns having different thicknesses are formed.

Referring to FIG. 5D, the upper and lower layers 25 and 26 and the passivation layer 31 are etched using the first and second photosensitive patterns 90a and 90b as a mask (operation S14). If the forming of the passivation layer is omitted, only the base metal layer 29 is etched during the etching process.

Specifically, the base metal layer 29 and the passivation layer 31 are formed into desired patterns during a photolithography process, using the first and second photosensitive patterns 90a and 90b as a mask. In FIG. 5D, the base metal layer 29 and the passivation layer 31 are etched to form contact layers 20, 22, and 25, gate electrodes 21 and 26, and a gate line 23. The photolithography process may be performed using any suitable photolithography method.

Referring to FIG. 5E, the first photosensitive pattern 90a is removed, and the thickness of the second photosensitive pattern 90b is reduced, during the etching of the photosensitive pattern (operation S15). Specifically, an etch back process is performed to remove the first photosensitive pattern 90a and reduce the thickness of the second photosensitive pattern 90b.

Since the first photosensitive pattern 90a is thinner than the second photosensitive pattern 90b, the first photosensitive pattern 90a is completely removed, while the second photosensitive pattern 90b is reduced in thickness. Here, the etching process may be performed using any suitable etching method, such as dry etching or wet etching.

Referring to FIG. 5F, the first portion 31a of the passivation layer 31 is removed (operation S16). If the passivation layer 31 is omitted, operation S16 is unnecessary. Specifically, the first portion 31a is removed by an etching process. However, since the second photosensitive pattern 90b remains, the second portion 31b of the passivation layer 31 is not etched. The etching process may be performed using any suitable etching method.

Referring to FIG. 5G, the second photosensitive pattern 90b is removed (operation S17). Specifically, the remaining second photosensitive pattern 90b is removed by, e.g., ashing. For example, the substrate 10 having the second photosensitive pattern 90b may be introduced into an ashing chamber. In the ashing chamber, the photosensitive film, which is an organic component, may react with oxygen plasma ions and thus, be converted into a gas.

As shown in FIG. 5G, the gate electrode 26 and the gate line 23 are exposed, while gate electrode 21 is covered with the second portion 31b of the passivation layer 31. That is, the second portion 31b remains on the gate driver. Therefore, the second portion 31b may be formed to be thicker than the first portion 31a of passivation layer 31, in operation S12.

Referring to FIG. 5H, a plating process is performed on the first portion 27a of the upper layer 27, to form a plating layer 27c (operation S18). That is, since the plating process is performed, the upper layer 27a is formed into the thicker plating layer 27c.

Specifically, an electrolytic or electroless plating process is performed on the gate electrode 26 and the gate line 23, which may be used as seed layers, thereby increasing the thicknesses of the gate electrode 26 and the gate line 23. Since the gate electrode 21 is covered with the passivation layer 31, the gate electrode 21 is not plated. Accordingly, the gate electrode 26 and the gate line 23 are increased in thickness, thereby forming a low resistance wiring in the display area.

The gate electrode 26 and the gate line 23 may be plated with copper, aluminum, gold, silver, or an alloy of at least one of these materials. In particular, copper or a copper alloy may be used. Copper has far higher electrical conductivity than aluminum and does not exhibit significant electro-migration. Thus, copper can minimize wiring resistance.

The electrolytic or electroless plating process may be performed using any suitable plating process. In the electrolytic or electroless plating process, the gate electrode 26 and the gate line 23 serve as a seed layer. In the electrolytic plating process, a voltage is applied to the seed layer in a solution in which copper ions are dissolved, thereby plating a copper film on the seed layers. To reduce the resistance of the plated copper film, a heat treatment process may additionally be performed, at a temperature of approximately 200° C. In the electroless plating process, the seed layer is immersed in a plating solution containing metal, such as palladium (Pd), platinum (Pt), gold (Au), nickel (Ni), copper or silver, or metallic salts, such that the metallic salts are deposited on the surface of the seed layer. Then, the treated seed layer is immersed in a plating solution containing a low-resistance metal material. Accordingly, a thick metal layer is formed only on the surface of the seed layer, by a reduction reaction of the metallic salts on the surface of the seed layer.

Å final thickness of the gate electrode 26 and the gate line 23 after plating may be in a range of about 5,000 to 20,000 Å. In the above thickness range, a low resistance wiring can be realized, which, in turn, solves the problem of the RC delay. Consequently, an LCD with high resolution can be manufactured.

As described above, since a low resistance wiring having a thick metal plating layer can be formed in an LCD, the RC delay can be reduced. In the above-described method of forming a wiring, a low resistance wiring having a thick metal layer is formed in the display area but not in the gate driver (peripheral area), by the same electrolytic or electroless plating process. Therefore, the problem of the gate driver not operating when a thick metal wiring is formed can be solved. In addition, since a low resistance wiring is formed by the electrolytic or electroless plating process, vacuum sputtering equipment is not used, thus reducing manufacturing costs and time.

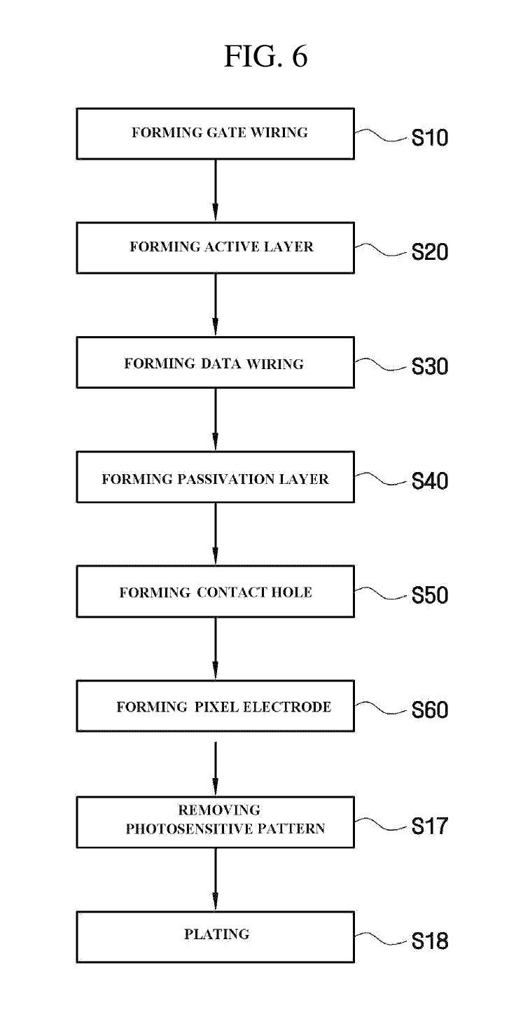

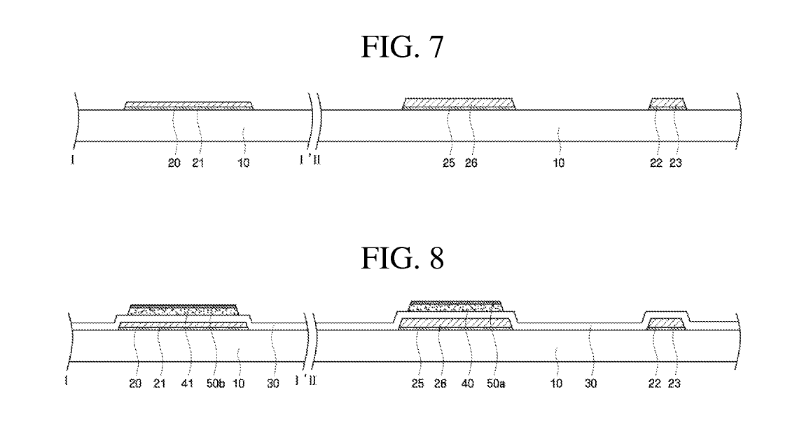

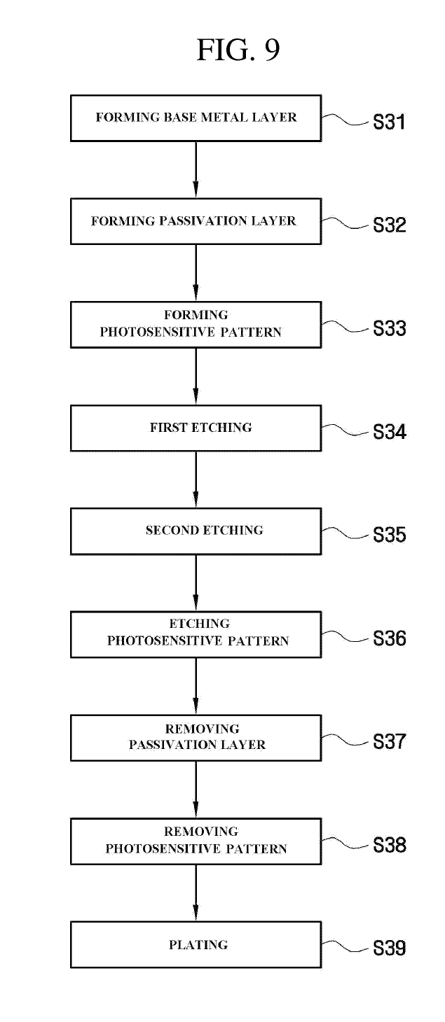

FIG. 6 is a flowchart illustrating a method of manufacturing an LCD, according to another exemplary embodiment of the present invention. FIG. 9 is a flowchart illustrating a process of forming a data wiring in the method of FIG. 6. FIGS. 7, 8, 10A through 10I, and 11 through 13 are cross-sectional views respectively illustrating processes of the method of FIG. 6.

Referring to FIG. 6, the method of manufacturing an LCD includes forming a gate wiring (operation S10), forming an active layer (operation S20), forming a data wiring (operation S30), forming a passivation layer (operation S40), forming a contact hole (operation S50), and forming a pixel electrode (operation S60).

A substrate 10 provided in the current exemplary embodiment is divided into a display area in which an image is displayed and peripheral area disposed around the display area. For example, a gate driver may be formed on the peripheral area. FIGS. 7, 8, 10A through 10I and 11 through 13 are cross-sectional views taken along the lines I-I′ and II-II′ of FIG. 2.

Referring to FIG. 7, the forming of the gate wiring (operation S10) may be achieved by removing the second portion 31b of the passivation layer 31 (FIG. 5H) from the gate electrode 21. As such, the wiring shown in FIG. 7 is formed.

Referring to FIG. 8, a gate insulating film, an amorphous or polycrystalline silicon film, and a doped amorphous silicon film are formed on the gate electrodes 21 and 26 and the gate line 23. The amorphous or polycrystalline silicon film and doped amorphous silicon film are patterned to form active layers 40 and 41, and ohmic contact layer patterns 50a and 50b (operation S20). Then, the amorphous or polycrystalline film and the doped amorphous silicon film are etched to form the island-shaped active layers 40 and 41 and ohmic contact layer patterns 50a and 50b. The etching process may be performed using any suitable etching method, such as dry etching.

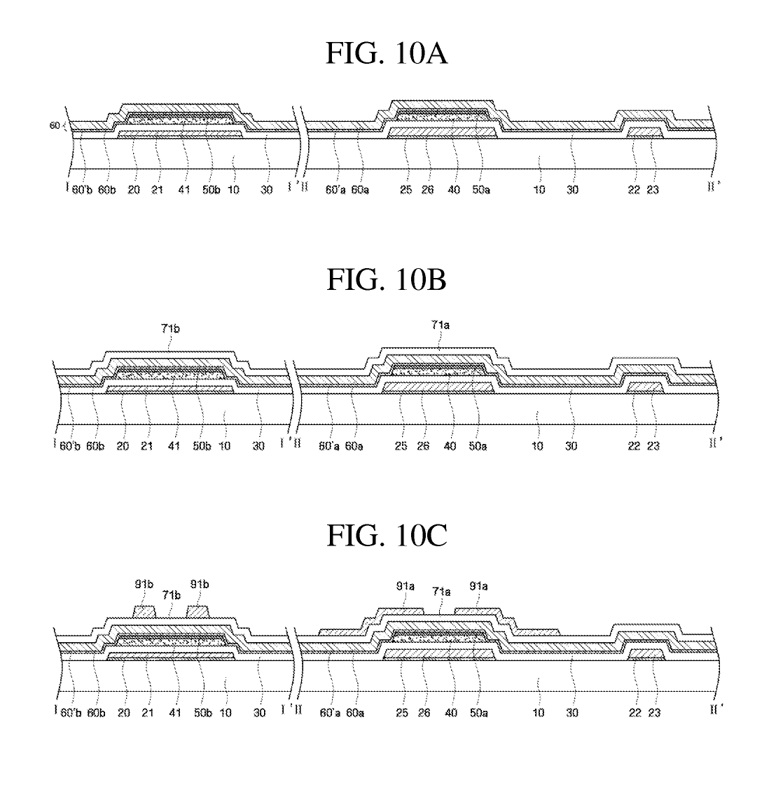

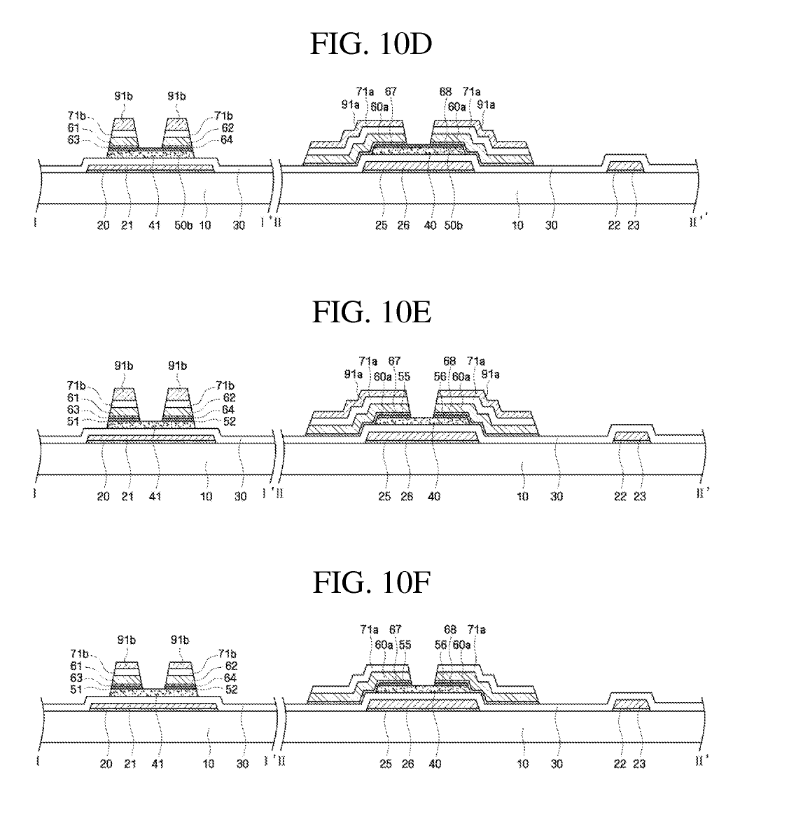

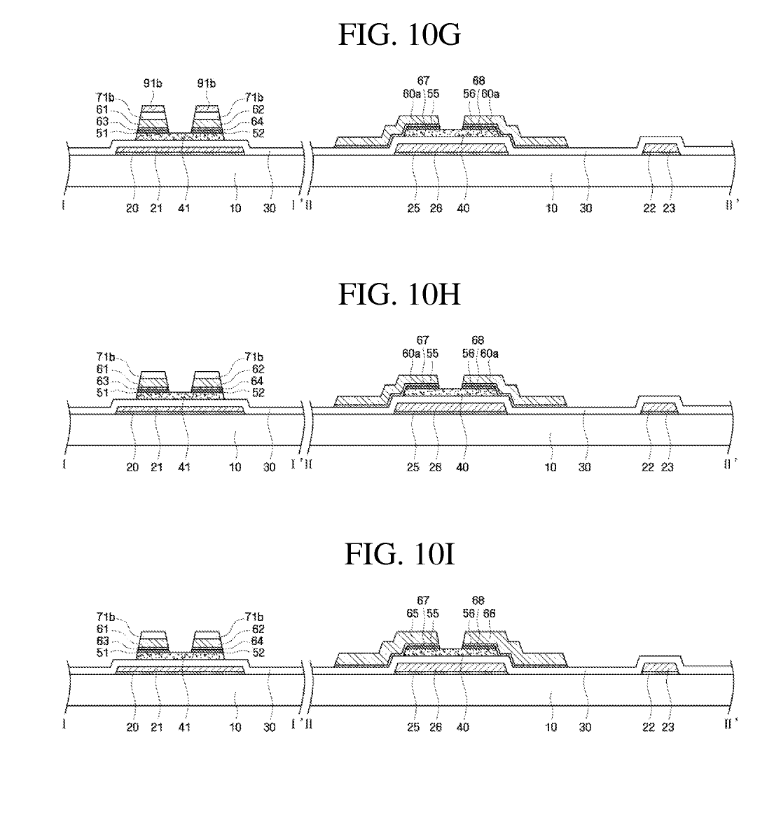

FIG. 9 is a flowchart illustrating the forming of the data wiring (operation S30). Referring to FIG. 9, the forming of the data wiring includes forming a base metal layer (operation S31); forming a passivation layer (operation S32); forming a photosensitive pattern (operation S33); performing a first etching process (operation S34); performing a second etching process (operation S35); etching the photosensitive pattern (operation S36); removing the passivation layer (operation S37); removing the photosensitive pattern (operation S38); and performing a plating process (operation S39). FIGS. 10A through 10I are cross-sectional views respectively illustrating processes of the forming of the data wiring.

Referring to FIG. 10A, base metal layer 60 is formed on the ohmic contact layer patterns 50a and 50b (operation S31). The base metal layer 60 includes a lower layer 60′ and an upper layer 60. The lower layer 60′ includes a first portion 60′a disposed in the display area of the substrate 10, and a second portion 60′b disposed in the peripheral area of the substrate 10. The upper layer 60 includes a first portion 60a disposed in the display area, and a second portion 60b disposed in the peripheral area. The upper layer 60 may be made of copper or a copper alloy. The lower layer 60′ may be formed of titanium. The lower layer 60′ increases the adhesion of the base metal layer 59 to other layers and may be omitted in some embodiments.

Operation S31 is similar to operation S11, except that the base metal layer 60 is formed on the ohmic contact layer patterns 50a and 50b. Therefore, a detailed description of operation S31 is omitted. The base metal layer 60 may be formed to a thickness of about 1,000 to 4,000 Å. In addition, the lower layer 60′b may be formed to enhance contact characteristics.

Referring to FIG. 10B, a passivation layer 71 is formed on the base metal layer 60 (operation S32). The passivation layer includes a first portion 71a disposed in the display area, and a second portion 71b disposed in the peripheral area. Operation S32 is similar to operation S12, and thus, a detailed description thereof is omitted. The passivation layer 31 may be omitted in some embodiments.

Referring to FIG. 10C, a first photosensitive pattern 91a having a first thickness is formed on the first portion of the passivation layer 71a, and a second photosensitive pattern 91b having a second thickness, which is greater than the first thickness, is formed on the second portion of the passivation layer 71b (operation S33). Operation S33 is similar to operation S13, and thus, a detailed description thereof is omitted.

Referring to FIG. 10D, the base metal layer 60 and the passivation layer 71 are etched using the first and second photosensitive patterns 91a and 91b as a mask (operation S34). If the passivation layer 71 is omitted, only the base metal layer 60 is etched.

Specifically, the base metal layer 60 and the passivation layer 71 are formed into desired patterns in a photolithography process, using the first and second photosensitive patterns 91a and 91b. The photolithography process may be performed using any suitable photolithography method known in the art. As a result of the first etching process (operation S34), the ohmic contact layer patterns 50a and 50b are partially exposed. In addition, drain and source electrodes 61 and 62 of the gate driver and titanium layers 63, 64, 67 and 68 are formed during the first etching process (operation S34).

Referring to FIG. 10E, the ohmic contact layer patterns 50a and 50b are etched using the first and second photosensitive patterns 91a and 91b as a mask (operation S35). As a result, predetermined regions of the active layers 40 and 41 are exposed. The predetermined regions of the active layers 40 and 41 are exposed to form channel regions of thin-film transistors, while ohmic contact layers 51, 52, 55, and 56, which disposed on opposing sides of the channel regions, are formed in the display area and the peripheral area.

Referring to FIG. 10F, the first photosensitive pattern 91a is removed, and the thickness of the second photosensitive pattern 91b is reduced during the etching of the photosensitive pattern (operation S36). Operation S36 is similar to operation S15, and thus, a detailed description thereof is omitted.

Referring to FIG. 10G, the first portion of the passivation layer 71a is removed (operation S37). Operation S37 is similar to operation S16, and thus, a detailed description thereof is omitted. If operation S32 is omitted, operation S37 is omitted.

Referring to FIG. 10H, the second photosensitive pattern 91b is removed (operation S38). As a result, the first portion of the upper layer 60a is exposed, while the drain and source electrodes 61 and 62 of the gate driver remain covered with the second portion of the passivation layer 71b. Operation S38 is similar to operation S17, and thus, a detailed description thereof is omitted.

Referring to FIG. 10I, the thickness of the upper base metal layer 60a is increased by an electrolytic or electroless plating process (operation S39). Specifically, a metal layer having an increased thickness is formed by performing an electrolytic or electroless plating process, using the upper base metal layer 60a as a seed layer.

That is, source and drain electrodes 65 and 66 having an increased thickness are formed by the electrolytic or electroless plating process, while the thickness of the drain and source electrodes 61 and 62 of the gate driver is not increased. That is, each of the source electrode 65 and the drain electrode 66 includes a base metal layer formed by sputtering and a plating layer formed on the base metal layer. On the other hand, each of the drain electrode 61 and the source electrode 62 of the gate driver includes only a base metal layer formed by sputtering.

Operation S39 is similar to operation S18, and thus, a detailed description thereof is omitted. A final thickness of the plated source electrode 65 and the drain electrode 66 may be about 5,000 to 20,000 Å.

The method described above provides a data wiring of an LCD, in which a low resistance wiring is formed only in a display area.

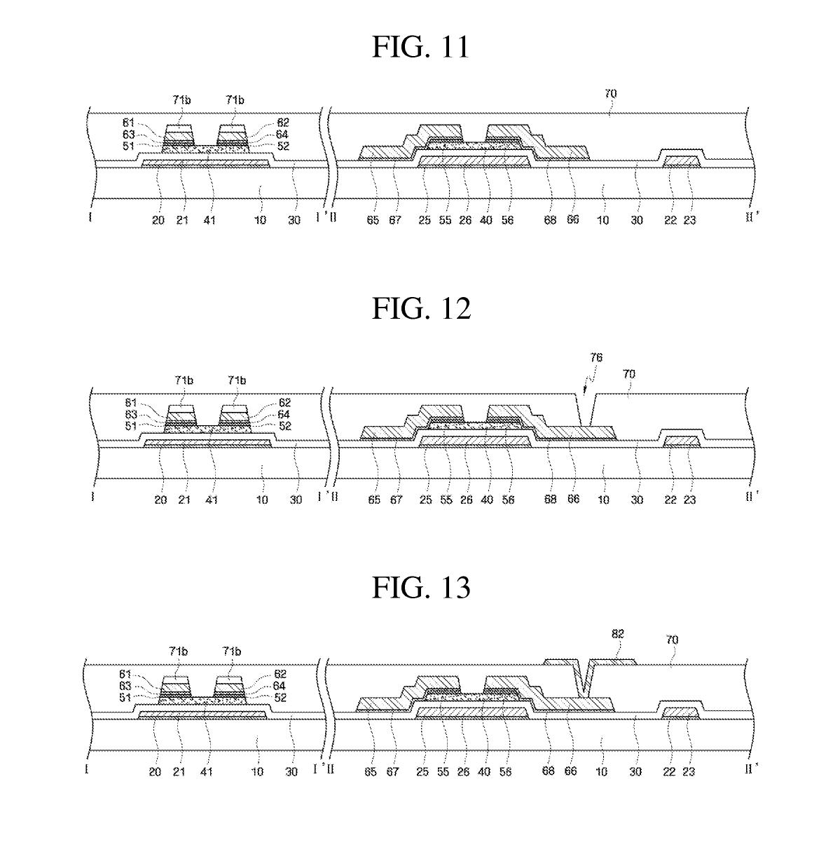

Referring to FIG. 11, a passivation layer 70, which is an insulating layer, is formed on the source electrodes 62 and 65, the drain electrodes 61 and 66, and the active layers 40 and 41 (operation S40). Specifically, the passivation layer 70 is formed by depositing an inorganic material, such as silicon nitride, or a low-k insulating material, such as a-Si:C:O or a-Si:O:F, on the source electrodes 62 and 65, the drain electrodes 61 and 66, and the active layers 40 and 41, using plasma enhanced chemical vapor deposition (PECVD.)

The second portion 71b of the passivation layer 71 is not removed, and the passivation layer 70 is formed on a top surface of the second portion 71b. Therefore, the second portion 71b may be formed thinner than the first portion 71a of the passivation layer 71.

Referring to FIG. 12, a contact hole 76 is formed in the passivation layer 70 to expose a predetermined portion of the drain electrode 66 (operation S50). Specifically, a photosensitive film is coated on the passivation layer 70. Then, the photosensitive film is patterned by exposing the photosensitive film to light using a mask, and developing the exposed photosensitive film. As a result of this photolithography process, the contact hole is formed in the passivation layer 70.

Referring to FIG. 13, a pixel electrode 82 is formed on the passivation layer 70 and connected to the drain electrode 66 through the contact hole 76 (operation S15). Specifically, an indium tin oxide (ITO) or indium zinc oxide (IZO) film is deposited on the passivation layer 70, and a photolithography process is performed on the ITO or IZO film to form the pixel electrode 82.

Using the method described above, an LCD having a low resistance wiring formed by a plating process is provided in a display area, but not in a gate driver disposed in a peripheral area, can be manufactured. In addition, since thin-film transistors of the display area and the peripheral area can be formed by the same process, the entire manufacturing process can be simplified, and costs can be reduced.

In a method of forming a wiring according to an exemplary embodiment of the present invention, a low resistance wiring can be formed. The low resistance wiring can reduce the RC delay of driving signals, thereby realizing a high-definition LCD. In a method of forming a wiring according to an exemplary embodiment of the present invention, thin-film transistors of a gate driver and a display area can be formed simultaneously, and a low resistance wiring can be formed without affecting the operation of the gate driver.

In a method of manufacturing a wiring according to an exemplary embodiment of the present invention, a thick metal film can be formed only in a desired region by using a plating process. In addition, the plating process can reduce the warping of a substrate, as compared with a case where sputtering is used to form the thick metal film. Since expensive equipment is not used when the thick metal film is formed by the plating process, manufacturing costs and time can be reduced, as compared with a case where the thick metal film is formed by sputtering.

However, the effects of the present invention are not restricted to the one set forth herein. The above and other effects of the present invention will become more apparent to one of daily skill in the art to which the present invention pertains by referencing the claims.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display device comprising:
a substrate comprising a display area in which an image is displayed and a peripheral area disposed outside of the display area;
a first metal wiring disposed in the display area; and
a second metal wiring disposed in the peripheral area and that constitutes a gate driver,
wherein the first metal wiring is thicker than the second metal wiring.

2. The display device of claim 1, wherein:
the first metal wiring comprises a sputtered base metal layer and an upper layer plated on the base metal layer; and
the second metal wiring comprises a sputtered base metal layer.

3. The display device of claim 1, wherein the first metal wiring comprises:
a sputtered base metal layer; and
a plating layer plated on the base metal layer.

4. The display device of claim 3, wherein the second metal wiring has the same thickness as the base metal layer of the first metal wiring.

5. The display device of claim 1, wherein:
the first metal wiring has a thickness of about 5,000 to about 20,000 Å; and
the second metal wiring has a thickness of about 1,000 to about 4,000 Å.

6. The display device of claim 1, wherein the first metal wiring and the second metal wiring each comprise copper or a copper alloy.

7. A method of manufacturing a display device, the method comprising:
forming a first metal wiring on the display area of a substrate; and
forming a second metal wiring that constitutes a gate driver on a peripheral area of the substrate,
wherein the first metal wiring is thicker than the second metal wiring.

8. The method of claim 7, wherein each of the first metal wiring and the second metal wiring comprises a gate electrode, a source electrode, and a drain electrode.

9. The method of claim 7, wherein the forming of the first metal wiring comprises:
forming a base metal layer by sputtering; and
forming a plating layer on the base metal layer by electrolytic or electroless plating.

10. The method of claim 9, wherein the second metal wiring and the base metal layer are formed in the same process.

11. A method of manufacturing a display device, the method comprising:
forming a base metal layer on a display area and a peripheral area of a substrate;
forming a first photosensitive pattern having a first thickness, in the display area on the base metal layer;
forming a second photosensitive pattern having a second thickness that is greater than the first thickness, in the peripheral area, on the base metal layer;
etching the base metal layer using the first and second photosensitive patterns as a mask;
performing an etch back process to remove the first photosensitive pattern and to reduce the thickness of the second photosensitive pattern; and
forming a plating layer on the exposed base metal layer by electrolytic or electroless plating.

12. The method of claim 11, further comprising:
forming a passivation layer on the base metal layer;
etching the passivation layer and the base metal layer; and
removing the passivation layer from the display area, after performing the etch back process.

13. The method of claim 12, further comprising removing the second photosensitive pattern from the peripheral area, after the removing of the passivation layer from the display area.

14. The method of claim 11, wherein the base metal layer comprises copper or a copper alloy.

15. The method of claim 11, wherein the base metal layer is formed by sputtering.

16. The method of claim 11, wherein the base metal layer has a thickness of about 1,000 to about 4,000 Å.

17. The method of claim 11, wherein the base metal layer and the plating layer have a combined thickness of about 5,000 to about 20,000 Å.

18. The method of claim 11, wherein:
the display region comprises pixels; and
the peripheral area comprises a gate driver.

19. A method of manufacturing a display device, the method comprising:
forming a gate wiring comprising a gate electrode, on a peripheral area of a substrate;
patterning forming a gate insulating film, an amorphous or polycrystalline silicon film, and a doped amorphous silicon film on the gate electrode, and patterning the amorphous or polycrystalline silicon film and the doped amorphous silicon film to form an active layer;
forming a base metal layer on the active layer;
forming a first photosensitive pattern having a first thickness, on the base metal layer, in the display area;
forming a second photosensitive pattern having a second thickness, which is greater than the first thickness, on the base metal layer, in the peripheral area;
etching the base metal layer using the first photosensitive pattern and the second photosensitive pattern as a mask;
etching the doped amorphous silicon film to expose the active layer, using the first photosensitive pattern and the second photosensitive pattern as a mask;
performing an etch back process to remove the first photosensitive pattern and expose the base metal layer in the display area, and to reduce the thickness of the second photosensitive pattern; and
forming a source electrode and a drain electrode on the base metal layer, in the display area, by electrolytic plating or electroless plating.

20. The method of claim 19, wherein the gate wiring of the display area is thicker than the gate wiring of the peripheral area.

21. The method of claim 19, wherein the forming of the gate wiring comprises:
forming a base metal layer on the substrate;
forming a first photosensitive pattern having a first thickness, on the base metal layer and in the display area;
forming a second photosensitive pattern having a second thickness, which is greater than the first thickness, on the base metal layer and in the peripheral area;
etching the base metal layer using the first photosensitive pattern and the second photosensitive pattern as a mask;
performing an etch back process to remove the first photosensitive pattern and to reduce the thickness of the second photosensitive pattern;
forming a metal layer on the base metal layer, in the display area, by electrolytic or electroless plating.

22. The method of claim 19, further comprising:
forming a passivation layer on the base metal layer;
etching the passivation layer while etching the base metal layer; and
removing the passivation layer from the display area, after performing the etch back process.

23. The method of claim 19, wherein the display area comprises pixels and the peripheral area comprises a gate driver.
